(19) United States
(12) Patent Application Publication
(10) Pub. No.: US 2014/0285971 A1
(43) Pub. Date: Sep. 25, 2014

(54) HAND POWER TOOL

(71) Applicant: Robert Bosch GmbH, Stuttgart (DE)

(72) Inventors: Manfred Schuele, Sulzbach-Laufen (DE); Helmut Wanek, Kirchheim/Neckar (DE); Cornelius Boeck, Kirchheim (DE); Joachim Schadow, Stuttgart (DE); Joerg Maute, Sindelfingen (DE); Florian Esenwein, Leinfelden-Echterdingen (DE); Manfred Lutz, Filderstadt (DE); Daniel Barth, Leinfelden-Echterdingen (DE)

(73) Assignee: Robert Bosch GmbH, Stuttgart (DE)

(21) Appl. No.: 14/220,314

(22) Filed: Mar. 20, 2014

(30) Foreign Application Priority Data
Mar. 21, 2013 (DE) 10 2013 204 975.7

(51) Int. Cl. B25F 5/00; H05K 7/20; B23Q 11/12

(52) U.S. Cl. CPC B25F 5/008; B23Q 11/126; H05K 7/20336
USPC 361/700; 62/3.2; 451/358

(57) ABSTRACT

A hand power tool, in particular an angle grinder, includes a drive unit, an electronic unit, and a cooling device configured, at least partially, to cool the drive unit and/or the electronic unit. The cooling device includes at least one cooling unit configured, at least partially, for localized cooling.

This application claims priority under 35 U.S.C. §119 to patent application no. DE 10 2013 204 975.7 filed on Mar. 21, 2013 in Germany, the disclosure of which is incorporated herein by reference in its entirety.

### BACKGROUND

A hand power tool has already been proposed.

### SUMMARY

The disclosure is based on a hand power tool, in particular an angle grinder, having a drive unit and an electronic unit, and having a cooling device provided, at least partially, for cooling the drive unit and/or the electronic unit.

It is proposed that the cooling device comprise at least one cooling unit, which is provided, at least partially, for localized cooling. A “drive unit” in this context is to be understood to mean, in particular, a unit provided, at least partially, to drive an insert tool coupled to the hand power tool, in an operating state. The drive unit preferably comprises at least one electric motor. It is also conceivable, however, for the drive unit to be realized, at least partially, such that it can be driven pneumatically and/or in another manner considered appropriate by persons skilled in the art.

An “electronic unit” in this context is to be understood to mean, in particular, a unit provided, at least partially, to control, in particular, the drive unit of the hand power tool, by open-loop and/or closed-loop control, at least when the hand power tool is in an operating state. Preferably, the electronic unit comprises at least one motor controller of the drive unit.

The electronic unit preferably has electronic components such as, in particular, at least one transistor, at least one capacitor, at least one processor, particularly preferably at least one field-effect transistor (MOSFET) and/or at least one bipolar transistor, in particular having an insulated gate electrode (IGBT).

“Cooling” in this context is to be understood to mean, in particular, an at least partial removal of thermal energy that is produced and/or given off, in particular when the hand power tool is in an operating state, in particular from at least one heat-critical component of the hand power tool. A “heat-critical” component in this context is to be understood to mean, in particular, an element, a unit and/or a region of the hand power tool whose operation and/or function may be negatively affected by the thermal energy produced, in particular when the hand power tool is in an operating state, and/or may be destroyed, at least partially, by the thermal energy produced, in particular when the hand power tool is in an operating state. In a particularly preferred exemplary embodiment, in particular, the drive unit and/or the electronic unit comprises/comprise the at least one heat-critical component of the hand power tool. Alternatively or additionally, the cooling device may also be provided, at least partially, for cooling another unit considered appropriate by persons skilled in the art, and/or another element and/or region considered appropriate by persons skilled in the art, such as, in particular, a grip region, of the hand power tool.

“Localized cooling” in this context is to be understood to mean, in particular, cooling in a small, locally delimited region in which, when the cooling unit is in an operating state, removal of thermal energy is substantially increased in comparison with a region adjoining the small, locally delimited region. A “small, local region” in this context is to be understood to mean, in particular, a region having a surface area that, in particular, is less than 500 mm², preferably less than 250 mm², preferably less than 100 mm², and particularly preferably less than 50 mm² “Substantially increased” in this context is to be understood to mean, in particular, that removal of thermal energy when the cooling unit is in an operating state is, in particular, at least 25%, preferably at least 50%, preferably at least 65%, and particularly preferably 80% higher in the small, locally delimited region than in the adjoining region. Preferably, when in an operating state, the cooling unit has a cooling power of at least 0.05 w/mm² in the small, locally delimited region.

The design according to the disclosure makes it possible to achieve advantageously good and preferably effective cooling, in particular at a hot spot, of the hand power tool. A preferably high power density of the hand power tool can thus be achieved.

It is additionally proposed that the cooling unit be provided for active cooling. “Active cooling” in this context is to be understood to mean, in particular, that thermal energy is carried away and/or routed away, at least partially, preferably at least almost completely, from a component to be cooled, in particular from the drive unit and/or from the electronic unit, in particular by means of a cooling stream. Preferably, by means of the active cooling, it is possible to achieve a removal of heat that, in particular, is at least 30%, preferably at least 50%, and particularly preferably at least 70% greater than in the case of a passive cooling such as, for example, an unforced and/or free convection cooling. Consequently, an advantageously effective design of the cooling unit can be achieved.

It is furthermore proposed that the cooling unit comprise at least one micro-cooling element. A “micro-cooling element” in this context is to be understood to mean, in particular, an element provided, at least partially, for, in particular, localized cooling. Preferably, for the purpose of cooling, or removing thermal energy, the micro-cooling element has a cooling surface area that, in particular, is less than 500 mm², preferably less than 250 mm², preferably less than 100 mm², and particularly preferably less than 50 mm². This makes it possible to achieve preferably precise cooling and an advantageously compact design of the cooling unit.

It is additionally proposed that the at least one micro-cooling element be constituted by a Peltier element and/or by a heat pipe. A “Peltier element” in this context is to be understood to mean, in particular, an element that, at least partially, is realized so as to be electrically conductive and that, at least partially, is provided to convert at least one temperature difference into at least one voltage and/or into at least one electric current, and/or that, at least partially, is provided to convert at least one voltage and/or at least one electric current into a temperature difference. A “heat pipe” in this context is to be understood to mean, in particular, an element comprising at least one coolant circuit that is realized, at least substantially, as a closed circuit, the coolant being provided, at least partially, to absorb thermal energy, in particular by a phase transition and/or by a change of state, and preferably to transport the energy, in particular automatically, particularly preferably by a capillary action, along a direction of main extent of the heat pipe. In addition, it is also conceivable for the micro-cooling element to be constituted by a heat-conducting element, which of a metal such as, for example, aluminum, or another thermally conductive material considered appropriate by persons skilled in the art. This makes it possible to achieve an advantageously high heat-flow density, and therefore a preferably compact design of the cooling unit and preferably good cooling of the drive unit and/or of the electronic unit.

It is additionally proposed that the cooling unit comprise at least one directing element, which is provided to direct a cooling fluid in a localized manner to a region to be cooled. A “directing element” in this context is to be understood to mean, in particular, an element provided, at least partially, to direct a stream of cooling fluid at least partially, preferably at least almost completely, in particular selectively, to a location to be cooled, and/or to influence and/or alter and/or to deflect, in particular by at least 5°, preferably by at least 10°, and particularly preferably by at least 20°, a flow direction of the cooling air stream. The cooling fluid stream preferably comprises a cooling air stream. It is also conceivable, however, for the cooling fluid stream to comprise a different cooling fluid, considered appropriate by persons skilled in the art, such as, for example, water, oil or the like. This makes it possible to achieve preferably selective, and therefore advantageously effective, cooling.

Furthermore, it is proposed that the cooling device comprise a further cooling unit, which is provided for large-area cooling. “Large-area cooling” in this context is to be understood to mean, in particular, cooling in a region of the hand power tool that, in particular, has a surface area of at least 500 mm², preferably at least 1000 mm², preferably at least 2500 mm², and particularly preferably at least 5000 mm², and that comprises at least 25%, preferably at least 50%, and particularly preferably at least 75% of a total inner surface area of the hand power tool. Preferably, the further cooling unit and the large-area cooling are provided to cool, at least mostly, at least one functional unit, preferably a plurality of functional units, of the hand power tool. It is thereby possible to achieve advantageously good and preferably reliable cooling of the hand power tool.

It is additionally proposed that the cooling unit and the further cooling unit be realized so as to be at least partially integral. Two units realized so as to be “partially integral” is to be understood to mean, in particular, that the units have at least one common element, in particular at least two, advantageously at least three common elements that are a constituent part, in particular a functionally important constituent part, of both units. An advantageously compact design of the hand power tool can be achieved as a result.

It is additionally proposed that the drive unit comprise at least one EC motor. An “EC motor” in this context is to be understood to mean, in particular, a brushless, electrically commutated direct-current motor. It is thereby possible to achieve a preferably high-power, advantageously compact and inexpensive design of the drive unit of the hand power tool.

Also proposed is a cooling unit of a hand power tool according to the disclosure.

Additionally proposed is a method for, in particular, localized cooling of a drive unit and/or electronic unit of a hand power tool according to the disclosure by means of a cooling unit.

The hand power tool according to the disclosure is not intended in this case to be limited to the application and embodiment described above. In particular, the hand power tool according to the disclosure may have individual elements, components and units that differ in number from a number stated herein, in order to fulfill a principle of function described herein.

### BRIEF DESCRIPTION OF THE DRAWINGS

Further advantages are given by the following description of the drawings. The drawings show two exemplary embodiments of the disclosure. The drawings, the description and the claims contain numerous features in combination. Persons skilled in the art will also expediently consider the features individually and combine them to create appropriate further combinations.

In the drawings:

FIG. 1 shows a perspective view of a hand power tool according to the disclosure,

FIG. 2 shows a schematic sectional view of the hand power tool according to the disclosure, and

FIG. 3 shows a schematic sectional view of an alternative design of the hand power tool according to the disclosure.

### DETAILED DESCRIPTION

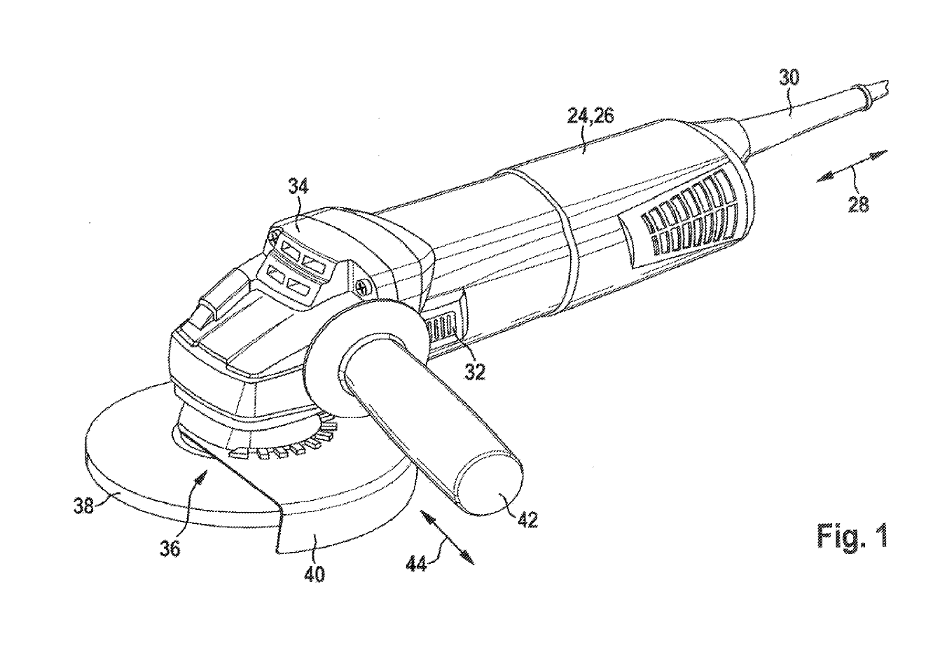

A hand power tool is represented in FIG. 1. The hand power tool is constituted by an angle grinder. Also conceivable, however, are other designs of the hand power tool considered appropriate by persons skilled in the art, such as, for example, as a power drill, hammer drill, oscillating hand power tool or orbital sander. The hand power tool comprises a housing 24. The housing 24 is made of a plastic. The housing 24 constitutes a main handle 26, which is provided to be gripped by an operating hand of an operator. A power cable 30 is disposed at one end of the housing 24, as viewed in the direction of main extent 28 of the hand power tool. The power cable 30 is provided to supply electrical energy to a drive unit 10 of the hand power tool. The power cable 30 is provided to be connected to an electrical power network. For this purpose, the power cable 30 has a plug element, not represented. It is also conceivable, however, for the hand power tool to be constituted by a battery-powered hand power tool. The hand power tool additionally has a switching element 32, which is designed to be operated by an operator. The switching element 32 is provided to activate the drive unit 10. The switching element 32 is constituted by a slide switch.

The hand power tool additionally has a transmission housing 34. The transmission housing 34 is connected to the housing 24, at an end of the housing 24 opposite to the power cable 30. The transmission housing 34 is made of a metal. The transmission housing 34 is made of aluminum. The hand power tool comprises a tool receiver 36, not represented in greater detail, which is provided to receive and captively hold an insert tool 38. The insert tool 38 is constituted by an abrasive disk. The insert tool 38 is detachably connected to the tool receiver 36. The tool receiver 36 is disposed at an open end of the transmission housing 34, as viewed perpendicularly in relation to the direction of main extent 28 of the hand power tool. The tool receiver 36 projects out of the transmission housing 34. In addition, a protective hood 40 is coupled to a bearing flange of the transmission housing 34. The protective hood 40 is detachably connected to the hand power tool.

The hand power tool additionally has an ancillary handle 42. The ancillary handle 42 is provided to be gripped by a further operating hand of the operator. The ancillary handle 42 is detachably coupled to the hand power tool. When the ancillary handle 42 is mounted on the hand power tool, a direction of main extent 44 of the ancillary handle 42 is perpendicular to the direction of main extent 28 of the hand power tool and parallel to a plane of main extent of the insert tool 38.

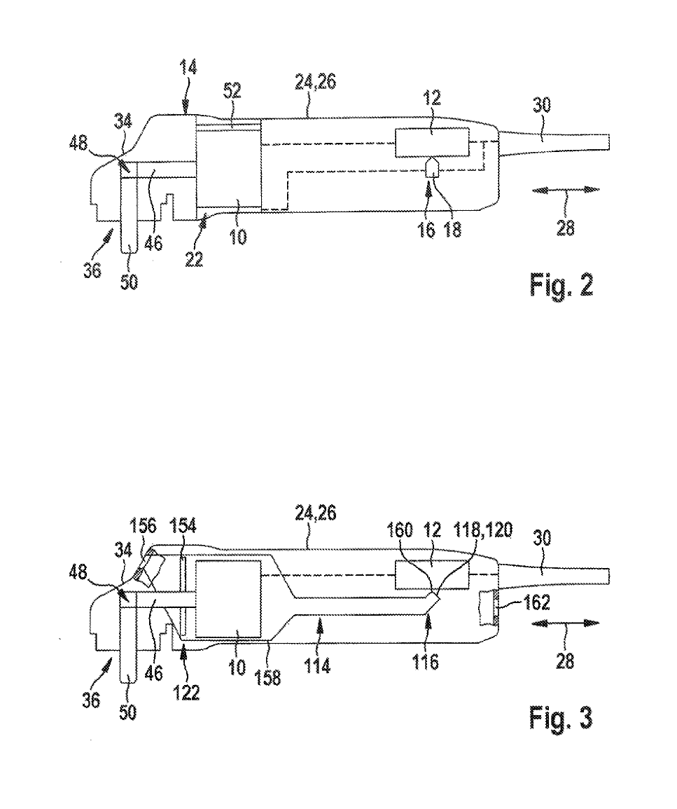

The hand power tool comprises the drive unit 10, an electronic unit 12 and a cooling device 14 (FIG. 2). The housing 24 of the hand power tool surrounds the drive unit 10, the electronic unit 12 and the cooling device 14. The drive unit 10 comprises an electric motor. The drive unit 10 comprises an EC motor. The drive unit 10 has an output shaft 46, which is connected to a drive shaft 50 via a transmission unit 48. The transmission unit 48 has a bevel gear transmission, not represented. The drive shaft 50 is provided for driving an insert tool, not represented here, which is coupled to the tool receiver 36. The drive shaft 50 is coupled to the tool receiver 36. The drive shaft 50 is connected to the tool receiver 36 in a form-fitting and/or force-fitting manner. The drive shaft 50 extends perpendicularly in relation to the output shaft 46. The drive shaft 50 is perpendicular to the direction of main extent 28 of the hand power tool.

The drive unit 10 is operatively connected to the electronic unit 12. The drive unit 10 is electronically connected to the electronic unit 12. The electronic unit 12 is provided for open-loop control or closed-loop control of the drive unit 10. Alternatively or additionally, the electronic unit 12 may also be provided for open-loop control or closed-loop control of a further functional unit considered appropriate by persons skilled in the art. The electronic unit 12 comprises field-effect transistors. The electronic unit 12 comprises metal-oxide semiconductor field-effect transistors (MOSFET). Alternatively or additionally, the electronic unit 12 may also comprise other electronic components considered appropriate by persons skilled in the art, such as, for example, a bipolar transistor having an insulated gate electrode (IGBT).

The cooling device 14 is provided for cooling the drive unit 10 and the electronic unit 12. Alternatively or additionally, it is also conceivable, however, for the cooling unit 14 to be provided for cooling a different functional unit of the hand power tool, considered appropriate by persons skilled in the art. The cooling device 14 has a cooling unit 16, which is provided for localized cooling. The cooling device 14 additionally has a further cooling unit 22, which is provided for large-area cooling. The further cooling unit 22 is provided for cooling the drive unit 10. The further cooling unit 22 comprises a cooling element 52, which has cooling fins. The cooling element 52 of the further cooling unit 22 is provided for convection cooling. The cooling element 52 of the further cooling unit 22 has an annular shape, and surrounds the drive unit 10 in a circumferential direction. The cooling element 52 of the further cooling unit 22 is in contact with an exterior of the drive unit 10. When in an operating state, the drive unit 10 heats up. The thermal energy is transferred to the cooling element 52 of the further cooling unit 22 by means of solid conduction. The cooling element 52 of the further cooling unit 22 has a high thermal conductivity, of at least 30 W/m*K, preferably of at least 50 W/m*K, particularly preferably of at least 80 W/m*K, preferably of at least 100 W/m*K, and particularly preferably of at least 200 W/m*K. The cooling element 52 of the further cooling unit 22 is realized so as to be electrically isolated from the drive unit 10. The thermal energy that the drive unit 10, when in an operating state, transfers to the cooling element 52 of the further cooling unit 22 is given off to an environment of the hand power tool by the cooling element 52 of the further cooling unit 22.

The cooling unit 16 provided for localized cooling comprises a micro-cooling element 18. The cooling unit 16 is provided to cool a part of the electronic unit 12. The cooling unit 16 is provided to cool a hot spot of the electronic unit 12. The hot spot of the electronic unit 12 is constituted by a power component of the electronic unit 12. The hot spot is constituted by a component of the electronic unit 12 that undergoes the greatest heating when in an operating state. Alternatively or additionally, it is also conceivable, however, for the cooling unit 16 to be provided for localized cooling of a part of the drive unit 10 or of a different functional unit of the hand power tool, considered appropriate by persons skilled in the art. The cooling unit 16 is provided for active cooling. The micro-cooling element 18 is constituted by a Peltier element. Alternatively or additionally, it is also conceivable for the micro-cooling element 18 to be constituted by a heat pipe, a micro-Peltier element or other cooling element considered appropriate by persons skilled in the art. The micro-cooling element 18 is provided for cooling when the hand power tool is in an operating state. It is also conceivable, however, for the micro-cooling element 18 to be realized so as to be controllable by open-loop or closed-loop control, irrespective of an operating state of the hand power tool.

The following descriptions and the drawings are limited substantially to the differences between the exemplary embodiments and, in principle, reference may be made to the drawings and/or the description of the other exemplary embodiments, in particular to FIGS. 1 and 2, in respect of components having the same designations, in particular in respect of components having the same references. In order to differentiate the exemplary embodiments, the number 1 has been prefixed to the references of the exemplary embodiment in FIG. 3.

Represented in FIG. 3 is an alternatively designed hand power tool, comprising a drive unit 10, and comprising an electronic unit 12, which are surrounded by a housing 24 and a transmission housing 34 and which, in their structure and function, correspond to the hand power tool already described. The hand power tool additionally has a cooling device 114 for cooling the drive unit 10 and the electronic unit 12. Alternatively or additionally, it is also conceivable, however, for the cooling device 114 to be provided for cooling a different functional unit of the hand power tool, considered appropriate by persons skilled in the art. The cooling device 114 has a cooling unit 116, which is provided for localized cooling. The cooling device 114 additionally has a further cooling unit 122, which is provided for large-area cooling. The further cooling unit 122 is provided for cooling the drive unit 10. The further cooling unit 122 comprises a fan element 154, which is provided to generate a cooling stream, in an operating state. The fan element 154 is constituted by a fan propeller. The fan element 154 is connected to the output shaft 46 of the drive unit 10 in a rotationally fixed manner. The fan element 154, when in an operating state, generates a cooling stream, which goes past the drive unit 10 in the direction of main extent 28 of the hand power tool, from an inlet opening 156 in the transmission housing 34. The cooling stream generated by the fan element 154 when in an operating state thereby absorbs thermal energy and carries the thermal energy away from the drive unit 10. The cooling stream flows inside a cooling channel 158.

The cooling channel 158 is open at an end of the cooling channel 158 that faces away from the inlet opening 156. At the end that faces away from the inlet opening 156, the cooling channel 158 has a directing element 120. The directing element 120 is provided to direct a cooling fluid of the cooling stream in a localized manner to a region to be cooled. The cooling fluid comprises air. It is also conceivable, however, for the cooling fluid of the cooling stream to comprise, for example, water, carbon dioxide and/or other fluid considered appropriate by persons skilled in the art. The directing element 120 is constituted by a nozzle 160. The nozzle 160 is provided to concentrate the cooling stream. The cooling stream emerging from the nozzle 160, out of the cooling channel 158, is directed on to the electronic unit 12 and provided to effect localized cooling of a part of the electronic unit 12. The housing 24 of the hand power tool additionally has an outlet opening 162, through which the cooling stream can be given off to an environment of the hand power tool. It is also conceivable for a flow direction of the cooling stream to run in the opposite direction.

The cooling unit 116 is provided for active cooling. The cooling unit 116 for localized cooling has a micro-cooling element 118, which is constituted by a directing element 120. The cooling unit 116 and the further cooling unit 122 are realized so as to be at least partially integral. The cooling unit 116 is provided to cool a hot spot of the electronic unit 12. The hot spot of the electronic unit 12 is constituted by a power component of the electronic unit 12. The hot spot is constituted by a component of the electronic unit 12 that undergoes the greatest heating when in an operating state. Alternatively or additionally, it is also conceivable, however, for the cooling unit 116 to be provided for localized cooling of a part of the drive unit 10 or of a different functional unit of the hand power tool, considered appropriate by persons skilled in the art.

What is claimed is:

1. A hand power tool, comprising:
a drive unit;
an electronic unit; and
a cooling device configured, at least partially, to cool one or more of the drive unit and the electronic unit, the cooling device including at least one cooling unit configured, at least partially, for localized cooling.

2. The hand power tool according to claim 1, wherein the at least one cooling unit is configured for active cooling.

3. The hand power tool according to claim 1, wherein the at least one cooling unit comprises at least one micro-cooling element.

4. The hand power tool according to claim 3, wherein the at least one micro-cooling unit includes one or more of a Peltier element and a heat pipe.

5. The hand power tool according to claim 1, wherein the cooling unit comprises at least one directing element configured to direct a cooling fluid in a localized manner to a region to be cooled.

6. The hand power tool according to claim 1, wherein the cooling device comprises a further cooling unit configured for large-area cooling.

7. The hand power tool according to claim 6, wherein the cooling unit and the further cooling unit are configured so as to be at least partially integral.

8. The hand power tool according to claim 1, wherein the drive unit comprises at least one EC motor.

9. A cooling device of a hand power tool, the hand power tool including a drive unit and an electronic unit, the cooling device comprising:
at least one cooling unit configured, at least partially, for localized cooling of one or more of the drive unit and the electronic unit.

10. A method for localized cooling of one or more of a drive unit and an electronic unit of a hand power tool, comprising:
cooling the one or more of the drive unit and the electronic unit with a cooling device, the cooling device including at least one cooling unit configured, at least partially, for localized cooling.

11. The hand power tool according to claim 1, wherein the hand power tool is configured as an angle grinder.
